(19) United States
(12) Patent Application Publication
(10) Pub. No.: US 2007/0218617 A1
(43) Pub. Date: Sep. 20, 2007

(54) Method of manufacturing semiconductor device

(75) Inventor: Tatsushi Kato, Suwa-shi (JP)

Correspondence Address: ADVANTEDGE LAW GROUP, LLC, 3301 NORTH UNIVERSITY AVE., SUITE 200, PROVO, UT, 84604, US

(73) Assignee: Seiko Epson Corporation, Tokyo (JP)

(21) Appl. No.: 11/724,629

(22) Filed: Mar. 15, 2007

(30) Foreign Application Priority Data
Mar. 16, 2006 (JP) 2006-072298

(51) Int. Cl. H01L 21/8238

(52) U.S. Cl. 438/199

(57) ABSTRACT

A method of manufacturing a semiconductor device includes: forming a first semiconductor layer on a semiconductor substrate; forming a second semiconductor layer above the first semiconductor layer, the second semiconductor layer having a smaller selection ratio of wet-etching than the first semiconductor layer; forming a hole having the semiconductor substrate as a bottom face in a supporting member holding area by removing by etching the second semiconductor layer and the first semiconductor layer in the supporting member holding area; forming a supporting member film above the semiconductor substrate to fill in the hole and to cover the second semiconductor layer; forming a mask pattern above the supporting member film, the mask pattern covering a supporting member area and exposing another area; dry-etching the second semiconductor layer and the first semiconductor layer in sequence using the mask pattern as a mask to form a supporting member abutting on the semiconductor substrate at the bottom face of the hole, and to form an aperture face under the supporting member, the aperture face exposing a side face of the first semiconductor layer; forming a hollow section between the second semiconductor layer and the semiconductor substrate by wet-etching the first semiconductor layer via the aperture face; and forming an insulating film inside the hollow section. In this case, the supporting member area includes a first supporting member area, a second supporting member area intersecting the first supporting member area, and a protruding area protruding from an intersection between the first supporting member area and the second supporting member area, and the supporting member holding area is disposed at a position overlapping the protruding area in plan view and distant from the intersection area.

### BACKGROUND OF THE INVENTION

1. Technical Field

Several aspects of the present invention relate to a method of manufacturing a semiconductor device, and in particular to a technology arranged to be capable of sufficiently wet-etching a first semiconductor layer (e.g., SiGe layer) in a supporting member area.

2. Related Art

In the recent semiconductor field, development of technology for forming devices in a semiconductor film on an insulating film substrate such as silicon-on-insulator has been activated. In particular, devices (i.e., SOI devices) formed on a silicon-on-insulator (SOI) substrate have possibilities of achieving low power consumption, high speed, and also low voltage driving.

Although there are known as a method of manufacturing SOI substrates, for example, a separation-by-implanted-oxygen (SIMOX) method and a lamination method for laminating two silicon substrates with an oxide film intervening therebetween, both of these methods require using specialized processes or specialized devices, and are not available with ordinary CMOS processes. Therefore, recently a separation-by-bonding-silicon-island (SBSI) method capable of forming an SOI structure on a bulk silicon substrate only with an ordinary CMOS process has been attracting attention (see, for example, T. Sakai et al., Second International SiGe Technology and Device Meeting, Meeting Abstract, pp. 230-231, May 2004).

A shape of an active layer in an integrated circuit in plan view (hereinafter referred to as “a planar shape”) is not generally specified, and is not necessarily required to be rectangular in plan view. For example, in memory cells of an SRAM, an L-shape is often used as the planar shape of a part of the active layer on the ground of the layout. In the case of forming the L-shaped active layer with the SBSI method, as shown in FIG. 11, a supporting member holding area 702 is required to be disposed on a corner of the supporting member area 701 having an L-shaped planar shape for supporting the supporting member in a balanced manner.

However, if the supporting member holding area 701 is provided as shown in FIG. 11, since an aperture face for introducing the etchant has been formed only inside of the L-shape in etching the SiGe layer with the SBSI method, the wet-etching proceeds towards the center of the corner section in one direction as illustrated with a solid arrow in FIG. 11. As a result, the etching range of the SiGe layer becomes long in the related art case, and there is a concern that the etchant might not sufficiently reach (in other words, the SiGe layer cannot sufficiently be wet-etched) the furthest part 703 of the supporting member area 701.

### SUMMARY

In view of such a technical problem as described above, an advantage of the invention is to provide a method of manufacturing a semiconductor device, which is capable of sufficiently wet-etching the first semiconductor layer in the supporting member area.

According to an aspect of the invention, a method of manufacturing a semiconductor device includes: forming a first semiconductor layer on a semiconductor substrate; forming a second semiconductor layer above the first semiconductor layer, the second semiconductor layer having a smaller selection ratio of wet-etching than the first semiconductor layer; forming a hole having the semiconductor substrate as a bottom face in a supporting member holding area by removing by etching the second semiconductor layer and the first semiconductor layer in the supporting member holding area; forming a supporting member film above the semiconductor substrate to fill in the hole and to cover the second semiconductor layer; forming a mask pattern above the supporting member film, the mask pattern covering a supporting member area and exposing another area; dry-etching the second semiconductor layer and the first semiconductor layer in sequence using the mask pattern as a mask to form a supporting member abutting on the semiconductor substrate at the bottom face of the hole, and to form an aperture face under the supporting member, the aperture face exposing a side face of the first semiconductor layer; forming a hollow section between the second semiconductor layer and the semiconductor substrate by wet-etching the first semiconductor layer via the aperture face, and forming an insulating film inside the hollow section. In this case, the supporting member area includes a first supporting member area, a second supporting member area intersecting the first supporting member area, a first protruding area protruding from an intersection between the first supporting member area and the second supporting member area in a longitudinal direction of the first supporting member area, and a second protruding area protruding from the intersection area in a longitudinal direction of the second supporting member area, and the supporting member holding area is disposed at least one of a position overlapping the first protruding area in plan view and distant from the intersection area and a position overlapping the second protruding area in plan view and distant from the intersection area.

In this case, “the semiconductor substrate” is, for example, a bulk silicon (Si) substrate. Further, “the first semiconductor layer” is, for example, a silicon-germanium (SiGe) layer, which can be obtained by epitaxial growth, and “the second semiconductor layer” is, for example, a Si layer, which can be obtained by epitaxial growth. Further, “the supporting member film” and “the insulating film” are, for example, silicon dioxide film (SiO₂).

According to the method of manufacturing a semiconductor device of this aspect of the invention, since a gap is caused around the corners of the intersection area, and the aperture faces for exposing the side face of the first semiconductor layer can be formed in the gap, the wet-etching of the first semiconductor layer in the intersection area through the plural aperture faces becomes possible. Since the wet-etching proceeds towards the center of the intersection area in a number of directions, the first semiconductor layer in the intersection area can sufficiently be removed.

According to another aspect of the invention, a method of manufacturing a semiconductor device, includes; forming a first semiconductor layer on a semiconductor substrate; forming a second semiconductor layer above the first semiconductor layer, the second semiconductor layer having a smaller selection ratio of wet-etching than the first semiconductor layer; forming a hole having the semiconductor substrate as a bottom face in a supporting member holding area by removing by etching the second semiconductor layer and the first semiconductor layer in the supporting member holding area; forming a supporting member film above the semiconductor substrate to fill in the hole and to cover the second semiconductor layer; forming a mask pattern above the supporting member film, the mask pattern covering a supporting member area and exposing another area; dry-etching the second semiconductor layer and the first semiconductor layer in sequence using the mask pattern as a mask to form a supporting member abutting on the semiconductor substrate at the bottom face of the hole, and to form an aperture face under the supporting member, the aperture face exposing a side face of the first semiconductor layer; forming a hollow section between the second semiconductor layer and the semiconductor substrate by wet-etching the first semiconductor layer via the aperture face, and forming an insulating film inside the hollow section. In this case, the supporting member area includes a first supporting member area, a second supporting member area intersecting the first supporting member area, and a protruding area protruding from an intersection between the first supporting member area and the second supporting member area, and the supporting member holding area is disposed at a position overlapping the protruding area in plan view and distant from the intersection area.

According to such a configuration, since the aperture faces for exposing the side face of the first semiconductor layer can widely be formed around the intersection area, the wet-etching of the first semiconductor layer in the intersection area can efficiently be performed. Since the wet-etching proceeds towards the center of the intersection area in a number of directions, the first semiconductor layer in the intersection area can sufficiently be removed.

According to still another aspect of the invention, a method of manufacturing a semiconductor device includes: forming a first semiconductor layer on a semiconductor substrate, forming a second semiconductor layer above the first semiconductor layer, the second semiconductor layer having a smaller selection ratio of wet-etching than the first semiconductor layer; forming a hole having the semiconductor substrate as a bottom face in a supporting member holding area by removing by etching the second semiconductor layer and the first semiconductor layer in the supporting member holding area; forming a supporting member film above the semiconductor substrate to fill in the hole and to cover the second semiconductor layer; forming a mask pattern above the supporting member film, the mask pattern covering a supporting member area and exposing another area; dry-etching the second semiconductor layer and the first semiconductor layer in sequence using the mask pattern as a mask to form a supporting member abutting on the semiconductor substrate at the bottom face of the hole, and to form an aperture face under the supporting member, the aperture face exposing a side face of the first semiconductor layer; forming a hollow section between the second semiconductor layer and the semiconductor substrate by wet-etching the first semiconductor layer via the aperture face; and forming an insulating film inside the hollow section. In this case, the supporting member area includes a first supporting member area, a second supporting member area intersecting the first supporting member area, and a protruding area protruding from at least one of the first supporting member area and the second supporting member area except the intersection area between the first supporting member area and the second supporting member area, and the supporting member holding area is disposed at a position overlapping the protruding area in plan view and distant from all of the intersection area, the first supporting member area, and the second supporting member area.

According to such a configuration, since the aperture faces for exposing the side face of the first semiconductor layer can widely be formed, the wet-etching of the first semiconductor layer in the intersection area can efficiently be performed. Since the wet-etching proceeds towards the center of the intersection area in a number of directions, the first semiconductor layer in the intersection area can sufficiently be removed.

### BRIEF DESCRIPTION OF THE DRAWINGS

The invention will now be described with reference to the accompanying drawings, wherein like numbers refer to like elements.

FIGS. 1A and 1B are explanatory views of a supporting member area 110 and supporting member holding areas 130 according to a first embodiment.

FIGS. 2A and 2B are explanatory views of a supporting member area 200 and a supporting member holding area 230 according to a second embodiment.

FIG. 3 is a view showing an example of an SRAM according to the second embodiment.

FIG. 4 is a view showing another example of an SRAM according to the second embodiment.

FIG. 5 is an explanatory view of a supporting member area 310 and a supporting member holding area 330 according to a third embodiment.

FIG. 6 is an explanatory view of a supporting member area 410 and supporting member holding areas 430 according to a fourth embodiment.

FIG. 7 is an explanatory view of a supporting member area 510 and supporting member holding areas 530 according to a fifth embodiment.

FIG. 8 is an explanatory view of a supporting member area 610 and supporting member holding areas 630 according to a sixth embodiment.

FIGS. 9A through 9D are diagrams (anterior half showing a method of manufacturing a semiconductor device according to an embodiment

FIGS. 10A through 10D are diagrams (posterior halt showing the method of manufacturing a semiconductor device according to the embodiment

FIG. 11 is a view showing a related art example and a problem thereof.

### DESCRIPTION OF THE EMBODIMENTS

Some embodiments of the invention will hereinafter be explained with reference to the accompanying drawings.

### First Embodiment

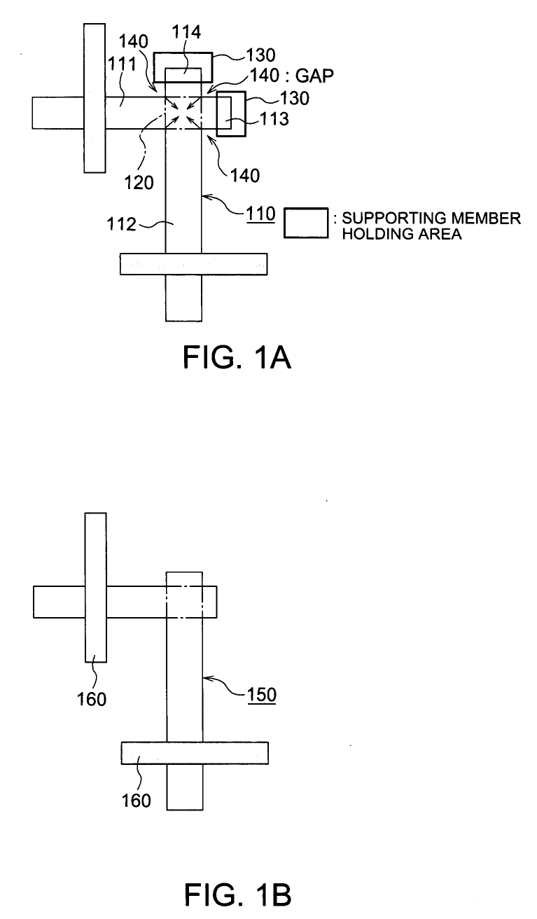

FIG. 1A is a plan view showing an example of a positional relationship between a supporting member area 110 and supporting member holding areas 130 according to a first embodiment of the invention.

As shown in FIG. 1A, in a method of manufacturing a semiconductor device according to the first embodiment, the supporting member area 110 is composed mainly of a first supporting member area 111, a second supporting member area 112 perpendicular to the first supporting member area 111, a first protruding area 113 protruding from an area (namely an intersection area) 120, where the first supporting member area 111 and the second supporting member 112 intersect with each other, in a longitudinal direction (namely a direction of an extension line) of the first supporting member area 111, and a second protruding area 114 protruding from the intersection area 120 in a longitudinal direction of the second supporting member area 112. Further, the supporting member holding areas 130 are each disposed at a position overlapping the first protruding area 113 in plan view and distant from the intersection area 120 and a position overlapping the second protruding area 114 in plan view and distant from the intersection area 120. According to such a positional relationship between the supporting member area 110 and the supporting member holding areas 130, gaps 140 are caused around corners of the intersection area 120.

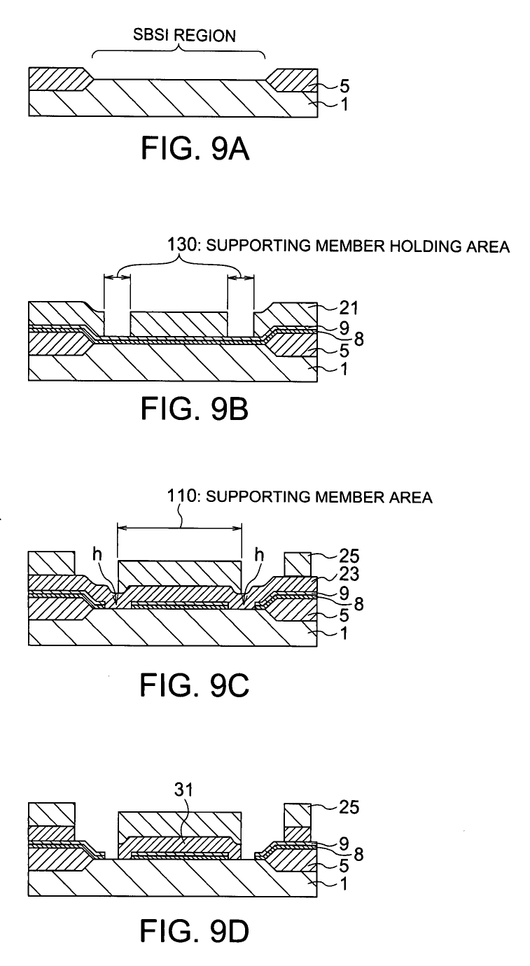

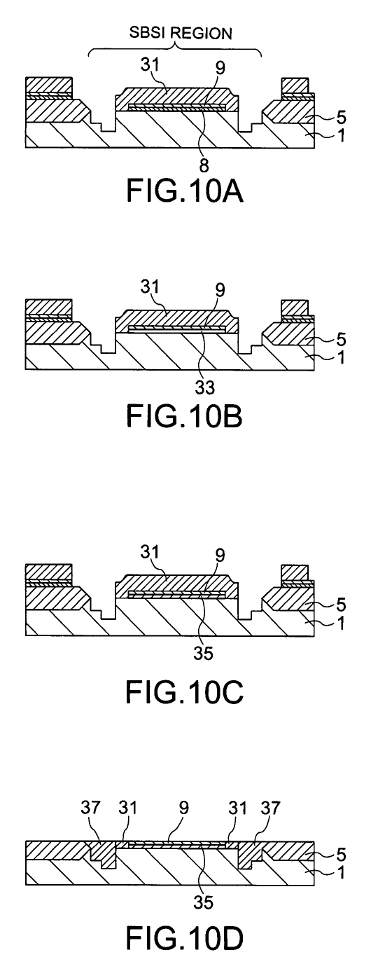

FIGS. 9A through 9D and 10A through 10D are sectional views showing a method of manufacturing a semiconductor device using the SBSI method. Firstly, an element separation layer 5 is formed on a surface of a silicon substrate 1, a bulk silicon wafer, with an LOCOS method. The element separation layer 5 is for separating a region (hereinafter referred to as “an SBSI region”) on which the SBSI method is preformed from a region (hereinafter referred to as “a bulk region”) where a bulk transistor is formed, and is formed of, for example, a silicon dioxide film (SiO₂ film).

Subsequently, as shown in FIG. 9B, an SiGe layer 8 is formed on the silicon substrate 1, and then an Si layer 9 is formed thereon. The SiGe layer 8 and the Si layer 9 are each formed by an epitaxial growth process. The film thickness of the SiGe layer 8 is, for example, in a range of about 10 through 200 nm, while the film thickness of the Si layer 9 is, for example, in a range of about 10 through 200 nm.

Subsequently, for example, a resist pattern 21 for exposing the supporting member holding area 130 existing inside the SBSI region and covering the entire area other than the area is formed on the silicon substrate 1 by photolithography. As shown in FIG. 1A, the planar shape of the supporting member holding area 130 is, for example, a rectangle. Further, by sequentially etching the Si layer 9 and the SiGe layer 8 in the supporting member holding areas 130 using the resist pattern 21 as a mask, holes each having the surface of the silicon substrate as the bottom are formed. After forming the holes, the resist pattern 21 is removed.

Subsequently, as shown in FIG. 9C, a supporting member film 23 is formed above the entire silicon substrate 1. The supporting member film 23 is, for example, a SiO₂ film, and is formed by a method such as CVD. The film thickness of the supporting film 23 is, for example, about 4000 A (angstrom). After forming the supporting member film 23, as shown in FIG. 9C, a resist pattern 25 covering the supporting member area 110 and exposing an area other than that area is formed on the supporting member film 23. Then, by etching the supporting member film 23 using the resist pattern 25 as a mask, the supporting member 31 is formed as shown in FIG. 9D. It should be noted that in the SBSI method, the remaining area of the supporting member area 110 after deduction of the supporting member holding area 130 forms the active layer, namely the area (hereinafter referred to as “an SOI forming area”) where the SOI structure is formed.

Subsequently, in FIG. 10A, the Si layer 9 and the SiGe layer 8 exposed under the supporting member 31 are removed by performing dry etching in sequence. In the dry etching process, the resist pattern 25 (see FIG. 9D) can be used as the mask, or the supporting member film 23 can be used as the (hard) mask. In the etching process for the supporting member film 23, a gas including, for example, CF₄ is used as the etching gas, in the etching process for the Si layer 9 and the SiGe layer 8, a gas including, for example, Cl₂ and O₂ is used as the etching gas. Thus, aperture faces exposing the side face of the Si layer 9 and the side face of the SiGe layer 8 are formed under the supporting member 31.

In this case, as shown in FIG. 1A, since the gaps 140 are caused around the corners of the intersection area 120 according to the positional relationship between the supporting member area 110 and the supporting member holding areas 130, the aperture face exposing the side face of the SiGe layer 8 is also formed in the gaps 140.

Subsequently, the resist pattern 25 (see FIG. 9D) is removed from above the silicon substrate 1. Then, only the SiGe layer 8 is removed by etching by making the etching liquid such as hydrofluoric/nitric acid contact the SiGe layer 8 and the Si layer 9 via a number of aperture faces provided to the supporting member 31. Thus, as shown in FIG. 10B, a hollow section 33 is formed between the silicon substrate 1 and the Si layer 9. As shown in FIG. 1A, since the wet etching proceeds towards the center of the intersection area 120 in a number of directions in this case, the SiGe layer in the intersection area 120 (see FIG. 1A) can sufficiently be removed, and the hollow section 33 can thus be formed in that area.

Subsequently, thermal oxidation is executed on the silicon substrate 1. In this case, the oxidizing species such as O2 reach not only the surface of the silicon substrate 1 exposed under the supporting member 31 but also the inside of the hollow section 33 passing through the aperture faces. Therefore, as shown in FIG. 10C, a SiO₂ film 35 is formed inside the hollow section 33. The SiO₂ film 35 formed inside the hollow section forms a BOX layer in the SOI structure.

Subsequently, a SiO₂ film is formed above the entire surface of the silicon substrate 1 with a method such as CVD to fill in the holes h and so on. Then, as shown in FIG. 10D, the SiO₂ film 37 is polished by, for example, CMP to planarize the entire surface above the silicon substrate 1. Further, wet etching with dilute hydrofluoric acid is executed on the silicon substrate 1 to expose the surface of the Si layer 9. Thus, a structure (i.e., the SOI structure) in which the upper surface of the Si layer 9 is exposed, and the bottom and the sides of the Si layer 9 are separated with the SiO2 film 35 or support member 31 is completed in the SOI forming region on the silicon substrate 1.

As described above, according to the method of manufacturing a semiconductor device relating to the first embodiment of the invention, since the gaps 140 are caused around the corners of the intersection area 120, and the aperture faces for exposing the side face of the SiGe layer 8 can be formed in the gaps 140, it becomes possible to perform wet-etching of the SiGe layer 8 in the intersection area 120 through a number of aperture faces. Since the wet-etching proceeds towards the center of the intersection area 120 in a number of directions, the SiGe layer 8 in the intersection area 120 can sufficiently be removed.

As a result, as shown in FIG. 1B, an active layer 150 having an L-shaped planar shape can be formed. In the case of forming, for example, CMOS in the L-shaped active layer 150, it is possible to form gate electrodes 160 so as to respectively traverse the active layer 150 in plan view as shown in FIG. 1B.

In this case, the silicon substrate 1 corresponds to “a semiconductor substrate” of the invention, the SiGe layer 8 corresponds to “a first semiconductor layer” of the invention, and the Si layer corresponds to “a second semiconductor layer” of the invention. Further, the resist pattern 25 corresponds to “a mask pattern” of the invention, and SiO₂ film 35 corresponds to “an insulating film” of the invention.

### Second Embodiment

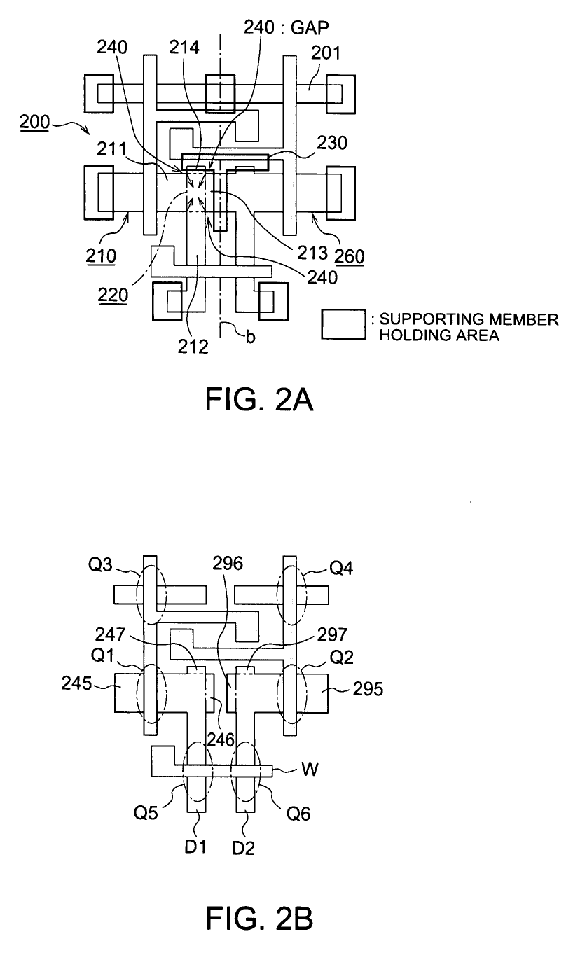

FIG. 2A is a plan view showing an example of a positional relationship between a supporting member area 200 and a supporting member holding area 230 according to a second embodiment. FIG. 2A shows an example of the case of forming an SRAM memory cell in the SBSI region.

As shown in FIG. 2A, a plurality of supporting member areas 200, 201 exist in the SBSI region in the second embodiment. Among them, the supporting member area 200 is separated into a supporting member area 210 and a supporting member area 260 across the boundary line b. The supporting member area 210 is an area where the supporting member for forming an active layer 245 (see FIG. 2B) is formed. Further, the supporting member area 260 is an area where the supporting member for forming an active layer 295 (see FIG. 2B) is formed.

As shown in FIG. 2A, the supporting member area 210 is mainly composed of a first supporting member area 211, a second supporting member area 212 perpendicular to the first supporting member 211, a first protruding area 213 protruding from an intersection area 220 in a longitudinal direction of the first supporting member area 211, and a second protruding area 214 protruding from the intersection area 220 in a longitudinal direction of the second supporting member area 212.

Further, the supporting member holding area 230 is disposed at a position overlapping the first protruding area 213 in plan view and distant from the intersection area 220 and a position overlapping the second protruding area 214 in plan view and distant from the intersection area 220. According to such a positional relationship between the supporting member area 210 and the supporting member holding areas 230, gaps 240 are caused around corners of the intersection area 220.

According to such a configuration, since the gaps 240 are caused around the corners of the intersection area 220, and the aperture faces for exposing the side face of the SiGe layer 8 can be formed in the gaps 240, it becomes possible to perform the wet-etching of the SiGe layer 8 in the intersection area through the number of aperture faces. Since the wet-etching proceeds towards the center of the intersection area 220 in a number of directions as illustrated with solid arrows in FIG. 2A, the SiGe layer 8 in the intersection area 220 can sufficiently be removed.

Thus, the active layer having the L-shaped planar shape can be formed with a correct shape through the SBSI process as described in the first embodiment as shown in FIG. 2B.

The SRAM shown in FIG. 2B is a storage device belonging the type forming every memory cell with six transistors. One CMOS is composed of MOS transistors Q1, Q3, and the other CMOS is composed of MOS transistors Q2, Q4. Further, MOS transistors Q5, Q6 are pass-gate transistors, and the gate electrode thereof is connected to a word line W. The source of the MOS transistor Q5 is connected to a bit line D1, and the source of the MOS transistor Q6 is connected to a bit line D2.

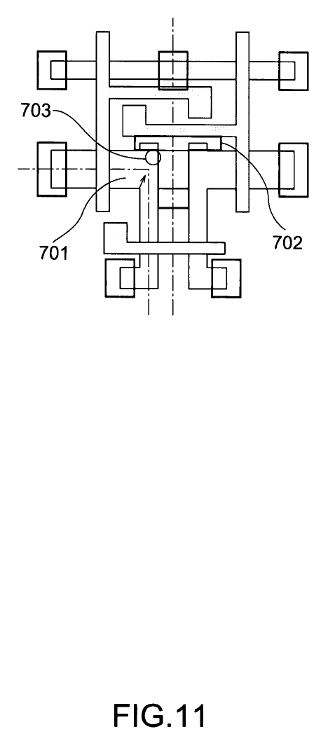

As is understood from comparison between FIG. 2A and FIG. 11, since there is no substantial difference in the planar shapes between the second embodiment and the related art example except the existence or nonexistence of the protruding sections, the planar shapes of the active layers 245 and 295 shown in FIG. 2B become substantially the same shapes as the related art example except the protruding sections 246, 247, 296, and 297. Accordingly, the SRAM layout in the related art can be used without making substantial changes. Since the SiGe layer in the intersection area 220 can sufficiently be removed only by making a slight change on the existing SRAM layout, the present embodiment of the invention can easily be applied to the existing SRAM layout.

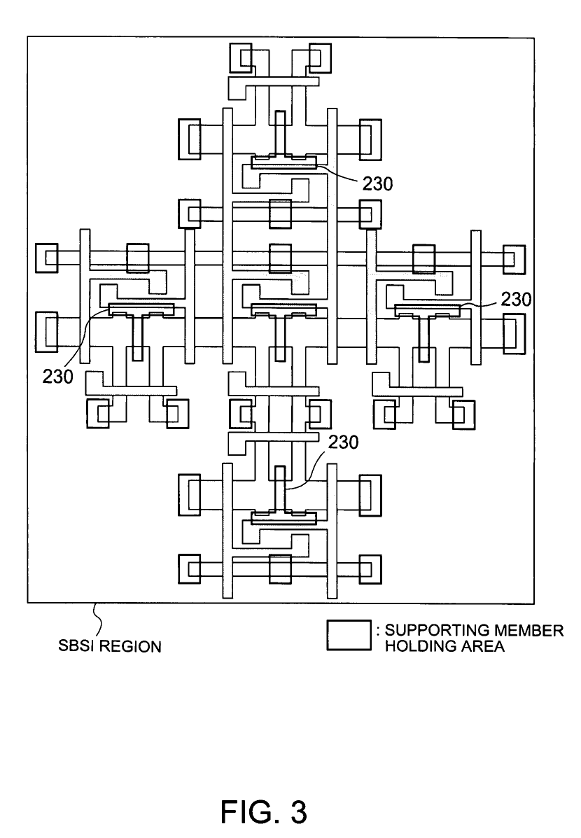

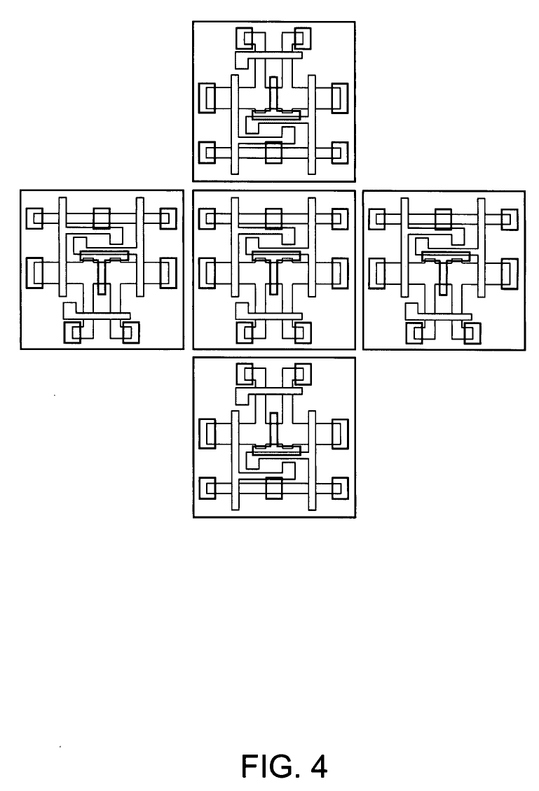

FIG. 3 is a plan view showing an example of an SRAM according to the second embodiment. This plan view shows an example of the case of forming five SRAM memory cells inside one SBSI region. Further, FIG. 4 is a plan view showing another example of an SRAM according to the second embodiment.

Although in the SBSI method, a number of SRAM memory cells can collectively be formed inside a single SBSI region as shown in FIG. 3, it is preferable to form only one memory cell of the SRAM inside a single SBSI region (namely, the memory cells are separated into individual cells) as shown in FIG. 4. As described above, by separating the memory cells into individual cells, and finely dividing the epi region, the crystallinity of the Si layer formed by the epitaxial growth method can be improved.

### Third Embodiment

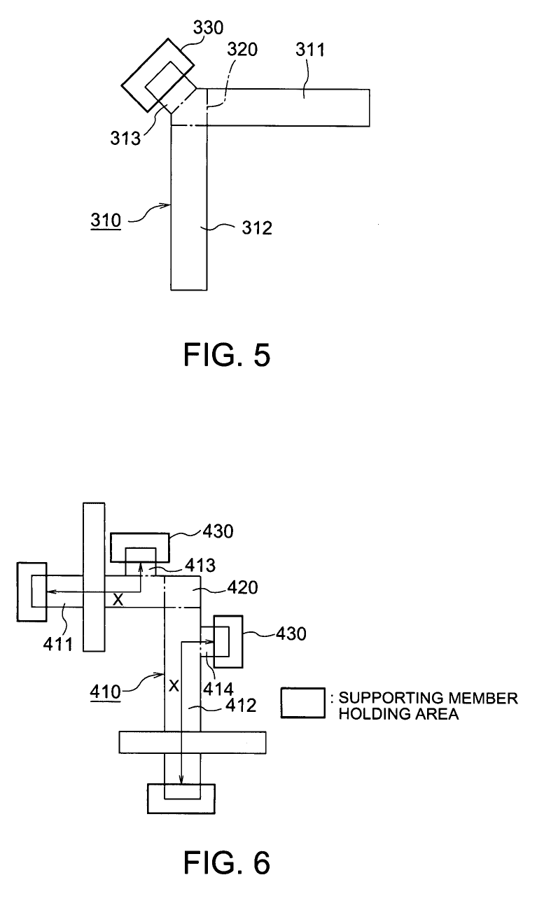

FIG. 5 is a plan view showing an example of a positional relationship between a supporting member area 310 and a supporting member holding area 330 according to a third embodiment of the invention. As shown in FIG. 5, the supporting member area 310 is mainly composed of a first supporting member area 311, a second supporting member area 312 perpendicular to the first supporting member area 311, and a protruding area 313 protruding on a slant from an intersection area 320 between the first supporting member area 311 and the second supporting member area 312. Further, the supporting member holding area 330 is disposed at a position overlapping the protruding section 313 and distant from the intersection area 320.

According to such a configuration, since the aperture faces for exposing the side face of the SiGe layer can widely be formed around the intersection area 320, the wet-etching of the SiGe layer in the intersection area 320 can efficiently be performed. Since the wet-etching proceeds towards the center of the intersection area 320 in a number of directions, the SiGe layer in the intersection area 320 can sufficiently be removed.

It should be noted that although the case of orthogonalizing (i.e., intersecting at a right angle) the first supporting member area 311 with the second supporting member area 312 is explained in the third embodiment, the angel of intersection between the first supporting member area 311 and the second supporting member area 312 is not limited to a right angle. For example, the inner angle formed by the first supporting member area 311 and the second supporting member area 312 intersecting each other can be 60°. Even in such a case, the same advantage as in the case with the orthogonal intersection can be obtained.

### Fourth Embodiment

FIG. 6 is a plan view showing an example of a positional relationship between a supporting member area 410 and supporting member holding areas 430 according to a fourth embodiment of the invention.

The supporting member area 410 is mainly composed of a first supporting member area 411, a second supporting member area 412 perpendicular to the first supporting member area 411, a first protruding area 413 protruding from the first supporting member area 411 except the intersection area 420 in a direction perpendicular to the longitudinal direction of the first supporting member area 411, and a second protruding area 414 protruding from the second supporting member area 412 except the intersection area 420 in a direction perpendicular to the longitudinal direction of the second supporting member area 412. Further, the supporting member holding areas 430 are each disposed at a position overlapping the first protruding area 413 in plan view and distant from all of the intersection area 420, the first supporting member area 411, and the second supporting member area 412, and a position overlapping the second protruding area 414 in plan view and distant from all of the intersection area 420, the first supporting member area 411, and the second supporting member area 412. In other words, in the fourth embodiment, the protruding areas 413, 414 are disposed on a part of the sides of the first supporting member area 411 and the second supporting member area 412 instead of the intersection area 420.

Further, as shown in FIG. 6, a distance X between any one of the supporting member holding areas 430 and another one of the supporting member holding areas 430 defined in the nearest position to the first one of the supporting member holding areas 430 is a distance within the extent that the gap formed by the SiGe selective etching is not broken down.

According to such a configuration, since the aperture faces for exposing the side face of the SiGe layer can widely be formed, the wet-etching of the SiGe layer in the intersection area 420 can efficiently be performed. Since the wet-etching proceeds towards the center of the intersection area 420 in a number of directions, the SiGe layer in the intersection area 420 can sufficiently be removed.

### Fifth Embodiment

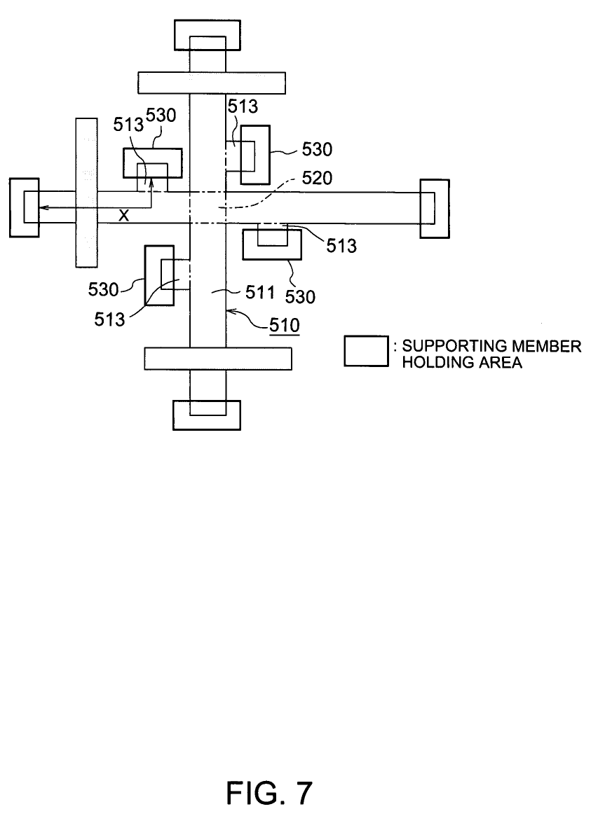

FIG. 7 is a plan view showing an example of a positional relationship between a supporting member area 510 and supporting member holding areas 530 according to a fifth embodiment of the invention.

As shown in FIG. 7, the supporting member area 510 is mainly composed of a supporting member area main body 511 having a cross planar shape, and protruding areas 513 respectively disposed on the middle of the sides composing the supporting member area main body 511. The supporting member holding areas 530 are each disposed at a position overlapping the protruding section 513 in plan view and distant from the supporting member area main body 511.

The number of protruding areas 513 is not particularly limited providing a distance X between any one of the supporting member holding areas 530 and another one of the supporting member holding areas 530 defined in the nearest position to the first one of the supporting member holding areas 530 is a distance within the extent that the gap formed by the SiGe selective etching is not broken down.

According to such a configuration, since the aperture faces for exposing the side face of the SiGe layer can widely be formed, the wet-etching of the SiGe layer in the cross intersection area 520 can efficiently be performed. Since the wet-etching proceeds towards the center of the intersection area 520 in a number of directions, the SiGe layer in the intersection area 520 can sufficiently be removed.

### Sixth Embodiment

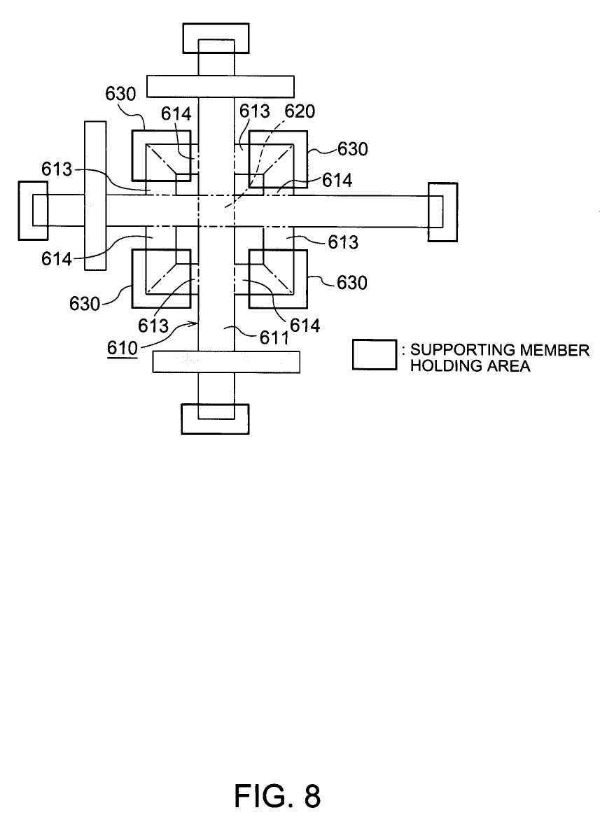

FIG. 8 is a plan view showing an example of a positional relationship between a supporting member area 610 and supporting member holding areas 630 according to a sixth embodiment of the invention.

As shown in FIG. 8, the supporting member area 610 is mainly composed of a supporting member area main body 611 having a cross planar shape, and protruding areas 613, 614 respectively disposed on the middle of the sides composing the supporting member area main body 611. The number of the protruding areas is increased in comparison with the case with the fifth embodiment, and the protruding areas 613 and 614 are joined each other at positions distant from the supporting member area main body 611. The supporting member holding areas 630 are disposed at positions overlapping the positions where the protruding areas 613, 614 are joined each other in plan view and distant from the supporting member area main body 611.

According to such a configuration, since the aperture faces for exposing the side face of the SiGe layer can widely be formed, the wet-etching of the SiGe layer in the cross intersection area 620 can efficiently be performed. Since the wet-etching proceeds towards the center of the intersection area 620 in a number of directions, the SiGe layer in the intersection area 620 can sufficiently be removed. Further, since the more the number of the protruding areas 613, 614 is, the stronger the force for supporting the supporting member area main body 611 becomes, it is effective for preventing the break down of the gaps formed by the SiGe selective etching.

What is claimed is:

1. A method of manufacturing a semiconductor device, comprising:
forming a first semiconductor layer on a semiconductor substrate;
forming a second semiconductor layer above the first semiconductor layer, the second semiconductor layer having a smaller selection ratio of wet-etching than the first semiconductor layer;
forming a hole having the semiconductor substrate as a bottom face in a supporting member holding area by removing by etching the second semiconductor layer and the first semiconductor layer in the supporting member holding area;
forming a supporting member film above the semiconductor substrate to fill in the hole and to cover the second semiconductor layer;
forming a mask pattern above the supporting member film, the mask pattern covering a supporting member area and exposing another area;
dry-etching the second semiconductor layer and the first semiconductor layer in sequence using the mask pattern as a mask to form a supporting member abutting on the semiconductor substrate at the bottom face of the hole, and to form an aperture face under the supporting member, the aperture face exposing a side face of the first semiconductor layer;
forming a hollow section between the second semiconductor layer and the semiconductor substrate by wet-etching the first semiconductor layer via the aperture face; and
forming an insulating film inside the hollow section,
wherein the supporting member area includes:
a first supporting member area;
a second supporting member area intersecting the first supporting member area;
a first protruding area protruding from an intersection between the first supporting member area and the second supporting member area in a longitudinal direction of the first supporting member area; and
a second protruding area protruding from the intersection area in a longitudinal direction of the second supporting member area,
the supporting member holding area is disposed at least one of a position overlapping the first protruding area in plan view and distant from the intersection area and a position overlapping the second protruding area in plan view and distant from the intersection area.

2. A method of manufacturing a semiconductor device, comprising:
forming a first semiconductor layer on a semiconductor substrate;
forming a second semiconductor layer above the first semiconductor layer, the second semiconductor layer having a smaller selection ratio of wet-etching than the first semiconductor layer;
forming a hole having the semiconductor substrate as a bottom face in a supporting member holding area by removing by etching the second semiconductor layer and the first semiconductor layer in the supporting member holding area;
forming a supporting member film above the semiconductor substrate to fill in the hole and to cover the second semiconductor layer;
forming a mask pattern above the supporting member film, the mask pattern covering a supporting member area and exposing another area;
dry-etching the second semiconductor layer and the first semiconductor layer in sequence using the mask pattern as a mask to form a supporting member abutting on the semiconductor substrate at the bottom face of the hole, and to form an aperture face under the supporting member, the aperture face exposing a side face of the first semiconductor layer;
forming a hollow section between the second semiconductor layer and the semiconductor substrate by wet-etching the first semiconductor layer via the aperture face; and
forming an insulating film inside the hollow section,
wherein the supporting member area includes:
a first supporting member area;
a second supporting member area intersecting the first supporting member area; and
a protruding area protruding from an intersection between the first supporting member area and the second supporting member area,
the supporting member holding area is disposed at a position overlapping the protruding area in plan view and distant from the intersection area.

3. A method of manufacturing a semiconductor device, comprising:
forming a first semiconductor layer on a semiconductor substrate;
forming a second semiconductor layer above the first semiconductor layer, the second semiconductor layer having a smaller selection ratio of wet-etching than the first semiconductor layer;
forming a hole having the semiconductor substrate as a bottom face in a supporting member holding area by removing by etching the second semiconductor layer and the first semiconductor layer in the supporting member holding area;
forming a supporting member film above the semiconductor substrate to fill in the hole and to cover the second semiconductor layer;
forming a mask pattern above the supporting member film, the mask pattern covering a supporting member area and exposing another area;
dry-etching the second semiconductor layer and the first semiconductor layer in sequence using the mask pattern as a mask to form a supporting member abutting on the semiconductor substrate at the bottom face of the hole, and to form an aperture face under the supporting member, the aperture face exposing a side face of the first semiconductor layer;
forming a hollow section between the second semiconductor layer and the semiconductor substrate by wet-etching the first semiconductor layer via the aperture face; and
forming an insulating film inside the hollow section,
wherein the supporting member area includes:
a first supporting member area;
a second supporting member area intersecting the first supporting member area; and
a protruding area protruding from at least one of the first supporting member area and the second supporting member area except the intersection area between the first supporting member area and the second supporting member area,
the supporting member holding area is disposed at a position overlapping the protruding area in plan view and distant from all of the intersection area, the first supporting member area, and the second supporting member area.
